(19) United States
(12) Patent Application Publication
(10) Pub. No.: US 2019/0066573 A1
(43) Pub. Date: Feb. 28, 2019

(54) LOAD-BEARING INTERACTIVE POLE VIDEO DISPLAY SYSTEM

(71) Applicants: Spencer I. Hochberg, Los Angeles, CA (US); Lauren Shaw, Los Angeles, CA (US)

(72) Inventors: Spencer I. Hochberg, Los Angeles, CA (US); Lauren Shaw, Los Angeles, CA (US)

(21) Appl. No.: 16/113,375

(22) Filed: Aug. 27, 2018

Related U.S. Application Data
(60) Provisional application No. 62/551,191, filed on Aug. 28, 2017.

(51) Int. Cl. G09G 3/32; G06F 3/044; H01L 25/075; G09F 23/00; G09F 9/33

(52) U.S. Cl. CPC G09G 3/32; G06F 3/044; H01L 25/0753; E04F 11/18; G09F 9/33; G09G 2370/16; G09G 2354/00; G09F 23/00

(57) ABSTRACT

The present invention discloses a load-bearing interactive pole video display system. This device allows for graphical video content to be displayed on the surface of a load-bearing pole-shaped structure that may be used in applications such as, but not limited to, railings, beams and dance poles. The core components of the invention are load-bearing internal structure, LED display, light transmissive covering, modular end fittings, power source, sensing and control electronics, which, generally speaking, are configured as follows: the LEDs are mounted to the internal load-bearing structure contained within the external light transmissive tube. Located at one or both ends of the railing are modular end fittings, which allow for connecting power, data and mechanical attachment of the pole or railing to support structures such as permanent or impermanent infrastructure or other modular installations.

### CROSS REFERENCE

This application claims priority to U.S. Provisional Patent Application No. 62/551,191, filed Aug. 28, 2017, the specification(s) of which is/are incorporated herein in their entirety by reference.

### FIELD OF THE INVENTION

The present invention relates to a load-bearing interactive pole video display system with an integrated cylindrical display capable of interfacing with internal and external sensors to control the displayed image, text, video and other graphic content.

### BACKGROUND OF THE INVENTION

Currently there are a number of products involving tube-shape LED (light-emitting diode) fixtures. Some solutions integrate lighting into permanent structural fixtures like handrails, but these solutions are limited to providing accent lighting, or to illuminate nearby surfaces and features. Current illuminated handrails lack an integrated display, interactivity, and full light coverage. Some stage lighting solutions offer visually customizable light fixtures, but their applications are limited because they are not structurally load-bearing.

Other load-bearing pole systems have included LED illumination in the past. For example, U.S. 2017/0282045 A1 of Glasner et al. discloses a dance pole having a rigid inner core and transparent outer tube with light points disposed in between.

However, the inventors herein have recognized potential issues with such systems. While the various embodiments described by Glasner et al. offer solutions for illuminating a load-bearing pole, they lack necessary features to create a cohesive video display.

The arrangement of an array of light emitters directly behind a transparent outer tube limits the system's ability to form recognizable features such as filled in shapes and text using pixel densities found in commercially available LED strips. Transparent tubes allow objects behind to be distinctly seen, giving a clear and direct view of the internal light source that makes each emitter appear bright and discrete.

This issue may be addressed by incorporating a diffusing layer, such as a transmissive, rather than transparent, outer tube. This enables the light from neighboring emitters to blend together, allowing the many individual emitters to act as one cohesive display.

Additionally, the multiple physical embodiments described by Glasner et al. are insufficient to create a cohesive video display from the light sources. In the first embodiment described by Glasner et al., light sources are mounted in cavities spaced around the circumference of a rigid inner core. Rectangular cavities as described and depicted are not well suited for allowing neighboring light channels to blend together. The described geometry along with a transparent outer tube is well suited for clearly displaying discrete light sources, but poorly suited for displaying shapes, text, video, etc.

An alternate geometry, as utilized by the load-bearing interactive pole video display system, features angled side-walls between the light channels that minimize the obstruction of the beam before it hits the diffusion layer.

A second embodiment described by Glasner et al. utilizes a rigid inner core with a polygonal cross section. A polygonal cross section is not ideal for creating a handrail or dance pole-sized video display systems with a diffusion layer because the number of facets is inversely related to the distance between the emitters and the diffuser. In this configuration, increasing the radial resolution requires reducing the distance between the light sources and the diffusion layer, limiting the effectiveness of the diffuser.

A third embodiment described by Glasner et al. utilizes scalloped bushings around a fixed center core to support a transparent tube. Bushings fixed to the center core create light obstructions normal to the pole's central axis, while it is sufficient to achieve the inventors' intention of displaying discrete light emitters, it is non-ideal for the application of displaying video, shapes, and text, due to dark bands that are created by the bushings blocking the spread of light.

The issues described above may be addressed by a load-bearing interactive pole video display system described herein, including an inner load-bearing structure typically comprises an extruded profile, shaped tube, or rod coupled to an extruded profile, that houses light emitters, typically LEDs, within channels in the structure, and an outer diffusing, light-transmissive covering. An extruded channel structure is cost effective and allows for the profile to be designed in such a way that the structure blocks the minimum amount of light from the LEDs while adequately supporting the outer diffusing tube.

The additional integration of sensing units to collect data from motion, touch, and other sources allow for a level of interactivity comparable with modern mobile devices.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### SUMMARY OF THE INVENTION

The present invention discloses a load-bearing interactive pole video display system with an integrated cylindrical LED display, made up of the following components: load-bearing internal structure, LED array, light transmissive covering with diffusion, modular end fittings, power source, sensing and control electronics. These components are connected as follows: the LEDs are mounted to channels in the internal load-bearing structure contained within the outer light transmissive tube. The pole video display system additionally includes modular end fittings, which allow for power connection, optional data connection, and further allow mechanical attachment of the pole system to support structures.

The device may also have one or more of the following: light diffusing and shock absorbing material such as foam between the outer covering and the inner structure, adaptive end fittings for specific system integrations, DC power supply and/or battery, slip ring to allow device to spin while connected to power and data sources. The device may be responsive to touch, motion, sound, mobile devices and/or neighboring electronic devices such as but not limited to other pole systems. The device is capable of communicating via a wireless or wired network connection. Sensor data inputs may be generated by onboard sensing electronics or from external sources.

The invention will now be described more fully hereinafter with reference to the accompanying drawings, which are intended to be read in conjunction with both this summary, the detailed description and any preferred and/or particular embodiments and variations specifically discussed or otherwise disclosed. This invention may, however, be embodied in many different forms and should not be construed as limited to the embodiments set forth herein; rather, these embodiments are provided by way of illustration only and so that this disclosure will be thorough, complete and fully conveys the full scope of the invention to those skilled in the art.

As will be disclosed herein, the system may include an internal load-bearing structure comprises a central tube or rod providing structural stability to the pole display system, and an extruded structure having a plurality of channels for housing a plurality of light sources within, separated by a gap from a diffusing element. The central rod allows for a softer material such as aluminum to be used to form the channel structure. Other embodiments may omit the central rod if a single piece structure is extruded, milled or otherwise formed from a harder and stiffer material such as steel.

Each channel of the inner structure comprises a base and two angled sidewalls projecting outward and wherein a top surface of each sidewall is coupled to a portion of the inner surface of the light transmissive tube. In some embodiments, a total number of sidewalls of the extruded structure may be eight. The inner structure positions the plurality of light sources within the pole assembly system in an unobstructed manner, allowing for maximal blending to occur between adjacent light sources to optimize cohesive display properties.

The system may additionally include a light transmissive tube attached externally to the load-bearing inner structure covering the plurality of light sources and providing a uniform surface to the pole assembly system, as well as a diffusing layer to create a video display surface. Each of the central rod, the extruded structure (110), and the light transmissive tube may be coaxial, and wherein the light transmissive tube may be coupled to modular end fittings on either end.

The system may additionally include a plurality of sensors, allowing for various modes of user interaction. For example, a network of integrated capacitive touch sensing units comprises an input interface that may allow for user interaction to the pole display system or content. Other sensors, measuring parameters such as but not limited to sound and motion, provide additional data sources. Interactive elements may be used for a wide range of applications such as gamification, data collection, performance art, informative user interfaces, etc.

The system may additionally include a microcontroller unit (MCU) comprises memory and a processor operatively coupled to the circuit board, wherein the system processor executes instructions stored in memory to generate and display graphical content for the integrated cylindrical LED display, optionally incorporating data and user inputs, or display such content from external sources.

In some embodiments, the main circuit board is responsible for communication, processing, signal generation and power distribution. In some embodiments, the plurality of sensors may comprise internal sensors and external sensors, wherein the internal sensors may include one or more of more proximity sensors, capacitive touch sensors, motion sensors, microphone, light sensors, or other types of sensors coupled to the pole assembly system. In some embodiments, the external sensors may include one or more of: proximity sensors, capacitive touch sensors, motion sensors, microphone, light sensors, or other sensors located external to the pole assembly system.

In some embodiments, the plurality of light sources may comprise a grid of LED pixels, and wherein the two-dimensional graphical content includes video, patterns, shapes or text.

In some embodiments, the processor receives sensor data from the capacitive touch sensing units, determines the location where a user is touching the surface, and applies a modulation of the video content and/or update displayed text on the grid of pixels. In some embodiments, the data from the capacitive touch sensing units may be used as a functional user input to the system, such as swiping along the surface to control the brightness of the video display.

In some embodiments, the video display structure may be coupled to additional sensors, the additional sensors may include but are not limited to audio, light, and inertial measurement unit (IMU) sensors. The MCU may execute further instructions to receive one or more of: a sound level from the audio sensor, ambient light level from a light sensor, and impact level from the IMU sensor, then apply a modulation to the displayed video content and/or update displayed text based on the input.

Some of the unique and inventive technical features of the present invention are that it provides: a seamless display capable of outputting video content from a variety of sources, load-bearing pole structure enabling the integration of interactive video displays into devices, infrastructure and systems that are not typically illuminated; integrated cylindrical LED arrangement allowing for content display radially and along the length of the device; an optically diffusing layer separated from the light source by a gap; interactivity as a control system; and informative, safety-enhancing or aesthetically pleasing value adding experience. Without wishing to limit the invention to any theory or mechanism, it is believed that the technical feature of the present invention advantageously provides for a sensing, customizable, load-bearing, and illuminated pole video display system. None of the presently known prior references or work has the unique inventive technical feature of the present invention.

The present invention provides for a design that overcomes various technical challenges to find an optimal compromise between several competing objectives. As an example, one technical challenge is that the pole must be sufficiently load-bearing and rigid to minimize deflection for its uses, including but not limited to handrails or vertical dance poles, while maintaining sufficient spacing for acceptable light diffusion and blending. The present invention implements a design wherein the emitters are mounted in channels formed by an internal structure. The profile of the inner structure is such that the light source is housed safely, the obstruction of the light path is minimized, and a sufficiently sized gap exists between the light emitters and the outer diffusing layer/material, in order to optimize diffusing properties of the system.

As the emitters are increasingly recessed away from the diffusing surface, the light is able to spread more, reducing hotspots and creating a cohesive image. However, deeply recessing the emitters requires decreasing the diameter of the load-bearing center, increasing deflection under load, potentially leading to the failure of internal components and structural instability. Conversely, if the light sources are closer to an outer surface of the pole assembly, the pole assembly may be more rigid, and/or more load-bearing. In applications such as poles used for pole dancing, accommodating an industry standard outer diameter of 45 mm requires carefully balancing deflection and diffusion.

The present invention includes a light transmissive outer tube that acts as a diffusing filter for the emitted light, blending together the underlying array of pixels into a cohesive seamless video display surface. Diffused light appears smoother than direct light, prevents casting harsh shadows, and creates a cohesive image as the light emitted by one source is blended into the light emitted by adjacent sources. The resulting effect is more visually appealing and comfortable to look at in close proximity. Other design choices have been made to maximize the transmission and spread of the light to create the effect of a seamless cylindrical video display, improving the visual effect, readability of text, and identification of displayed video content.

As discussed, the invention has many different features, variations and multiple different embodiments. The invention has been described in this application at times in terms of specific embodiments for illustrative purposes and without the intent to limit or suggest that the invention conceived is only one particular embodiment. It is to be understood that the invention is not limited to any single specific embodiments or enumerated variations. Many modifications, variations and other embodiments of the invention will come to mind of those skilled in the art to which this invention pertains, and which are intended to be and are covered by both this disclosure. It is indeed intended that the scope of the invention should be determined by proper interpretation and construction of the disclosure, including equivalents, as understood by those of skill in the art relying upon the complete disclosure at the time of filing.

### BRIEF DESCRIPTION OF THE DRAWINGS

The features and advantages of the present invention will become apparent from a consideration of the following detailed description presented in connection with the accompanying drawings in which:

FIG. 1 shows one embodiment of a pole assembly system, including an outer light transmissive covering and end fittings.

FIG. 2A shows an internal load-bearing structure of the pole assembly system with channels to house a plurality of light sources.

FIG. 2B shows the light source inlaid into the channel to form a cylindrical video display, with end fittings coupled to ends of the pole assembly system.

FIG. 3 shows a cross section of the assembly, including a central load-bearing tube or rod, a channel structure that house the plurality of light sources, and the outer diffusing light transmissive covering.

FIG. 4 shows a cross-section of the assembly without the light sources.

FIG. 5 shows a non-limiting embodiment of a power and data distribution unit coupled to the inner tube or rod having connectors for coupling to and delivering power to the light sources positioned within the channel.

FIG. 6 shows a non-limiting embodiment of an end fitting that includes a recessed pocket to hold a microcontroller unit (MCU).

FIG. 7 shows a non-limiting example of a capacitive touch sensing unit overlaid on top of the light source.

FIG. 8 shows a non-limiting embodiment of an end fitting coupled to the pole assembly. Channels in the end fitting align with channels formed by the extruded structure to allow for wiring to be routed the display.

FIG. 9 shows a schematic block diagram of the MCU. Microcontroller (1102) and Power and Data Distribution Unit (1110) may be located on the same circuit board.

FIG. 10 is a flowchart detailing an exemplary process of controlling a display on the pole assembly based on sensor data received from a plurality of sensors coupled to the pole assembly system.

### DESCRIPTION OF PREFERRED EMBODIMENTS

Following is a list of elements corresponding to a particular element referred to herein:

| | |
|---|---|
| 100 | pole assembly system |
| 102 | outer tube |
| 104 | end fittings |
| 106 | fasteners |
| 108 | inner tube or rod |
| 110 | channel structure |
| 112 | light sources |
| 300 | cross-section |
| 304 | plurality of channels |
| 305 | channel |
| 306 | sidewalls |
| 310 | inner surface |
| 316 | depth of channel |
| 318 | mean width of channel |
| 320 | gap between inner tube and outer tube |
| 322 | outer surface of inner tube or rod |
| 402 | channel base |
| 404 | first sidewall |
| 406 | second sidewall |
| 408 | width of sidewall |
| 410 | light opening |
| 412 | light occlusion |
| 414, 416 | semi-circular extruded parts |
| 602 | connector |
| 610 | power and data distribution unit |
| 702 | microcontroller unit (MCU) |
| 704 | cable |
| 706 | threaded holes |
| 812 | capacitive touch sensing unit |
| 1100 | block diagram |
| 1102 | microcontroller |
| 1104 | memory |
| 1106 | processor |
| 1108 | WIFI module |
| 1110 | power and data distribution unit |
| 1112 | proximity sensor |
| 1114 | sensors |
| 1116 | microphone |
| 1118 | light sensor |
| 1120 | inertial measurement unit (IMU) |
| 1122 | encoders |
| 1124 | LED strips |
| 1128 | server |

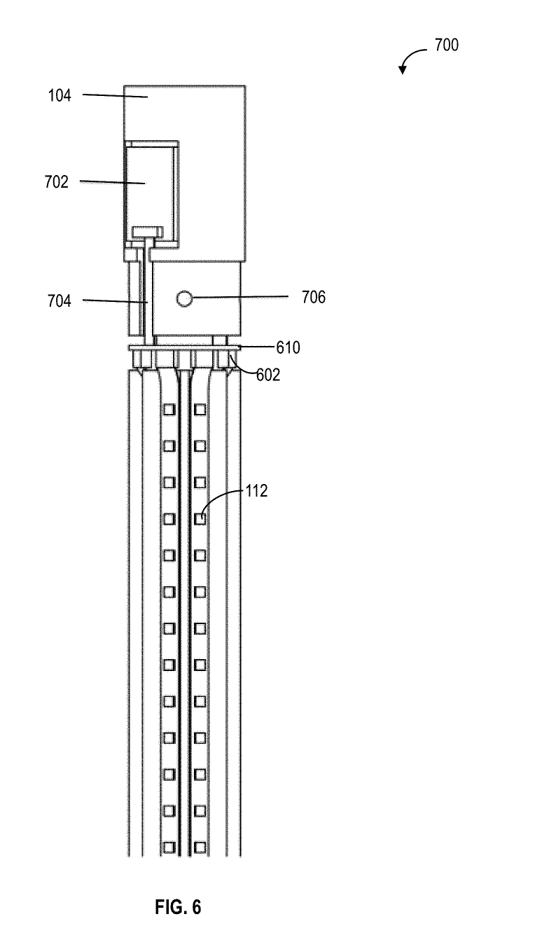

Referring to FIGS. 1-10, the present invention features a load-bearing interactive pole video display system (100) comprising a central tube or rod (108) with a channel structure (110) configured to house a plurality of light sources (112) within, placed concentrically within an outer diffusing light transmissive tube (102).

FIG. 1 shows the load-bearing interactive pole video display system (100) including the outer diffusing light transmissive tube (102) (hereafter interchangeably referred to as outer tube or light transmissive tube) coupled to two modular end fittings (104) at either end. The function of the outer tube (102) is to diffuse the light, provide a uniform surface capable of displaying video, patterns, shapes or text, as well as offer additional structure to the pole assembly system (100). The outer tube may be fastened to the end fittings (104) with fasteners (106) or friction fit.

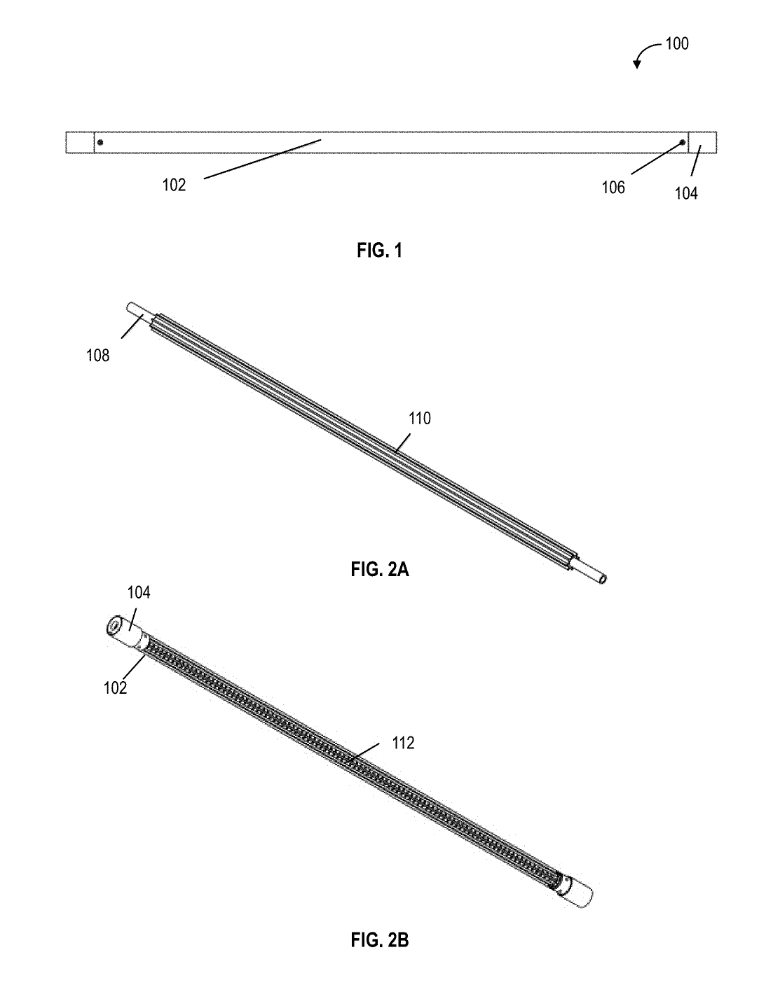

FIG. 2A shows the central tube or rod (108) and the channel structure (110) that make up the inner load-bearing structure. Hereafter, the central tube or rod may be interchangeably referred to as an inner tube, and the channel structure may be interchangeably referred to as extruded channel structure or extruded structure. The inner tube (108) serves as an internal structural element contributing to the strength and rigidity of the pole video display system. The channel structure (110) may be positioned concentrically around the inner tube, and is sized to fit inside the outer tube (102). More specifically, the inner tube (108), the channel structure (110), and the outer tube (102) are all coaxial, wherein Rᵢₙₙₑᵣ<R_{ES}<Rₒᵤₜₑᵣ, where Rᵢₙₙₑᵣ, R_{ES}, and Rₒᵤₜₑᵣ are the radii of the inner tube, the channel structure, and the outer tube respectively. In other embodiments, the inner load-bearing structure may be constructed as a single load-bearing internal structure.

The inner tube (108) may be uninterrupted throughout the illuminated portion of the pole video display system (100), with end fittings (104) fastened to both sides. In non-limiting embodiments, the channel structure (110) may be mechanically fastened to the inner tube (108) using adhesive, rivets, fasteners or alternate methods. In some embodiments, the video display system may be coupled to other tubes that do not have an inner tube, or any other structural components, without deviating from the scope of the invention. In some embodiments, the inner tube may be composed of steel, the channel structure may be composed of aluminum, and the outer tube may be composed of a light transmissive material capable of evenly diffusing light such as polycarbonate or acrylic. As such, the inner tube may be the primary load-bearing portion of the pole assembly, reinforced by the channel structure.

FIG. 2B shows the plurality of light sources (112) laid in channels of the channel structure (110). In a non-limiting example, the plurality of light sources may include an array of LEDs. The arrays of LEDs (or LED strips) may be positioned along the length of the pole assembly and inlaid into the recessed areas of the channel structure (110) resulting in a cylindrical video display that allows for visibility from all angles. Herein, the LED strips are arranged to form a grid of individually controlled pixels. In a non-limiting example, the channel structure (110) may include eight channels for holding eight strips of LEDs. Herein, there is a one-to-one correspondence with the number of the channels formed on the channel structure (110) and the number of strips of LEDs used. In non-limiting embodiments, the LED strips (112) may be fastened to bottom of channels of the channel structure (110) using a thermally conductive adhesive backing to effectively dissipate heat, provide electrical insulation, and keep the LEDs in place. The end fittings (104) are fastened to the inner tube (108) using methods including but not limited to set screws (106), threading, welding, press-fit or adhesive bonds.

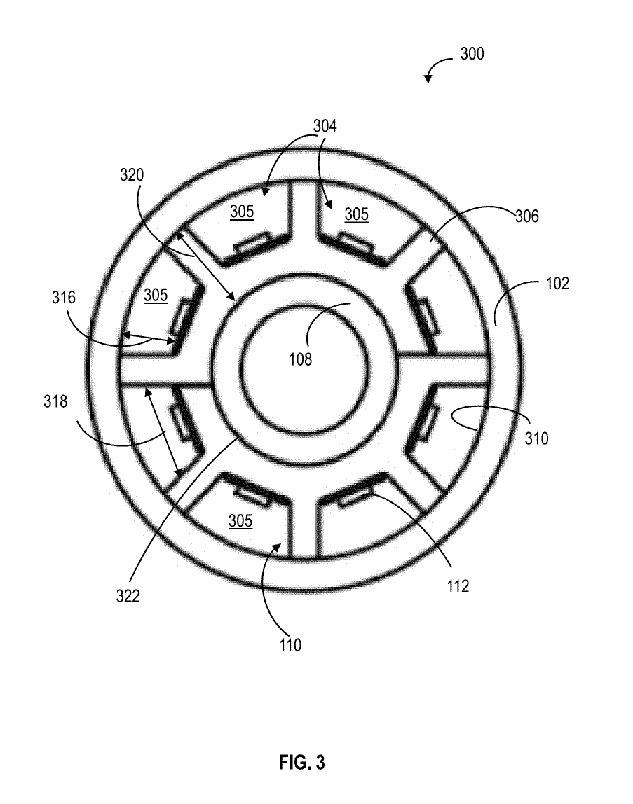

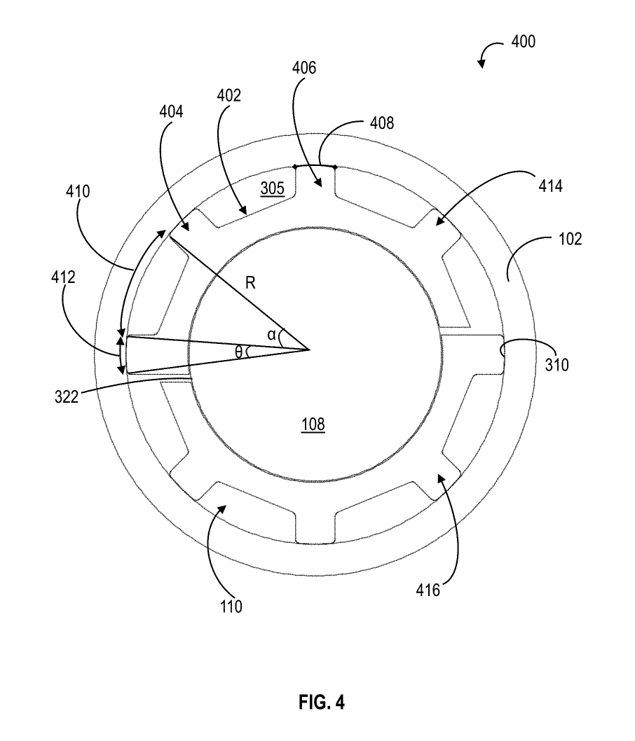

FIGS. 3 and 4 shows a cross section (300) of the pole assembly system, including the inner tube (108), the channel structure (110), and outer tube (102) covering the entire video display assembly. FIG. 4 shows the cross-section without the LEDs and FIG. 3 shows an alternate cross-section with the LED strips (112) positioned within channel structure (110). The inner tube (108) is the primary load-bearing structure composed of steel, for example. The outer tube (102) is positioned concentrically around the inner tube (108) and separated from the inner tube by a gap (320). The channel structure (110) extends across the gap (320) between the inner and the outer tube. The channel structure (110) is used to hold or position the LEDs within the pole assembly in an unobstructed manner, as explained below.

The channel structure (110) includes a plurality of sidewalls (306) forming a plurality of channels (304) in the gap (320) between the inner and the outer tube. Each channel (305) of the plurality of channels (304) is formed between two sidewalls (306). The number of channels included in the extruded structure may be based on the display requirements of the pole assembly. In a non-limiting embodiment, the channel structure (110) may include eight channels (304). In other examples, the channel structure may include higher or lower number of channels, without deviating from the scope of the invention. Herein, each channel houses a LED strip as a light source.

The channel structure (110) may be formed by coupling or joining two semi-circular pieces (414 and 416) or formed as a single circular piece. Each channel (305) of the plurality of channels (304) includes a base (402) coupled to a first sidewall (404) and a second sidewall (406). Herein, the base (402) is coupled to the inner tube (108) and the first and the second sidewalls are coupled the outer tube (102). More specifically, the base (402) is coupled to an outer surface (322) of the inner tube (108) and the first and the second sidewall are coupled to an inner surface (310) of the outer tube (102).

Each sidewall includes an arc segment or width (408) that is in face-sharing contact with the inner surface (310) of the outer tube (102) along specific locations. Herein, the number of locations where the sidewalls (306) are in contact with the inner surface (310) depends on the number of channels or the number of extrusions of the structure. In a non-limiting example, the channel structure may include a total of 8 sidewalls thereby forming 8 channels in the pole assembly. In other non-limiting example, the structure may include more or fewer sidewalls, without deviating from the scope of the invention.

Each LED is positioned within the channel by attaching the LED strip to the base (402) of the channel. Herein, the LED strip is not in contact with the inner or the outer tube, but is positioned at the base (402) of the channel (304) between the sidewalls (306). Herein, the channels may have angled sidewalls which allow light to be projected obliquely out of the pole assembly. Since the LEDs are not in contact with the inner tube or the outer tube, they will not be damaged when the pole assembly is touched, rotated, or bent within allowable range. Additionally, the channel structure keeps the light path clear of obstructions, allowing the unoccluded light sources to be evenly diffused and cumulatively form a video display.

In some embodiments, parameters such as inner radius r, height h of the extrusion, mean width w of the channels, and thickness t of the channel structure may be selected based on size, stiffness, and diffusion criteria. The outer radius R of the channel structure may be substantially equal to the inner radius of the outer tube (102).

The dimensions of the inner tube (108), the channel structure (110), and the outer tube (102) may be determined based on loading and deflection requirements of the pole assembly. In some embodiments, the inner tube may be composed of steel and include an inner diameter of about ¾″ and an outer diameter of about 1″. Inner tubes of other dimensions may be used without deviating from the scope of the invention.

In some embodiments, the dimensions of the outer tube may be selected based on one or more of: practical application-specific requirements, dimensions of the inner tube, a height of the channels and/or the extrusions, and LED properties. In some embodiments, the thickness of the polycarbonate material may be about ⅛″, which allows for a sufficient outer diameter of the load-bearing assembly while allowing light from the LEDs in the channels to diffuse through the medium to create a cohesive video display. In some embodiments, the length of the polycarbonate outer tube is such that it covers the entire inner assembly up to the end fittings.

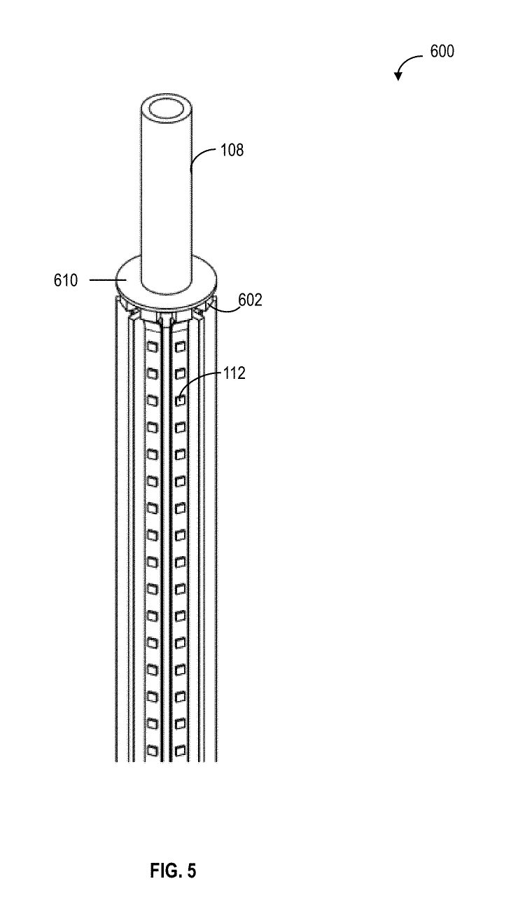

FIGS. 5-7 show one possible configuration of the electronic components in the pole assembly (100). The pole assembly (100) includes a ring-shaped power and data distribution unit (610) coupled to one end of the pole assembly to minimize the space needed for power and data connection. Herein, the power and data distribution unit (610) includes a central hole through which the inner tube (108) is inserted. Power wires may be directly connected to the power and data distribution unit (610), and then distributed to all subsystems of the pole assembly. Herein, each connector (602) on the underside of the power and data distribution unit (610) delivers power and data to each LED strip and additionally allows bi-directional communication between the microcontroller unit (MCU) (702) and capacitive touch sensing units (812) located along the channels of the pole assembly.

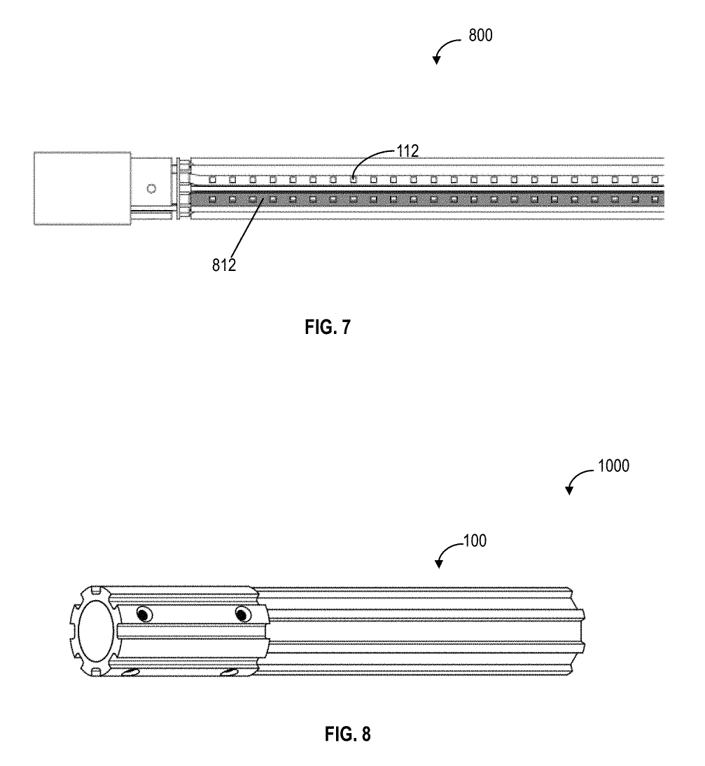

FIG. 7 shows a sensing unit (812) that may be laid over the light source (112). In some embodiments, the sensor component may be a capacitive touch sensing unit. The capacitive touch sensing unit may be used to locate a position/location where a user touches the pole video display system. Herein, the components may use a network of connected electrodes that are distributed radially and axially throughout the structure to determine the location. As a non-limiting example, the touch sensing circuit (812) may be printed on a circuit board which includes openings that correspond with each light source, so that the light can pass through the component unobstructed. The capacitive touch sensing system integrated into a video display may enable user input in the form of gestures and a control interface similar to that found in modern mobile devices.

FIG. 8 shows an end fitting coupled to the pole assembly in an alternate embodiment than shown by figures FIGS. 5-7. Recessed areas in the end fitting align with channels formed by the extruded structure to allow for wiring to be routed the display. In one non-limiting example, an end fitting as shown is fastened inside of a steel tube. The steel tube may be used as an extension to the main structure, act as a mounting point for fixing the pole display assembly, and to house the MCU, wiring, and other components.

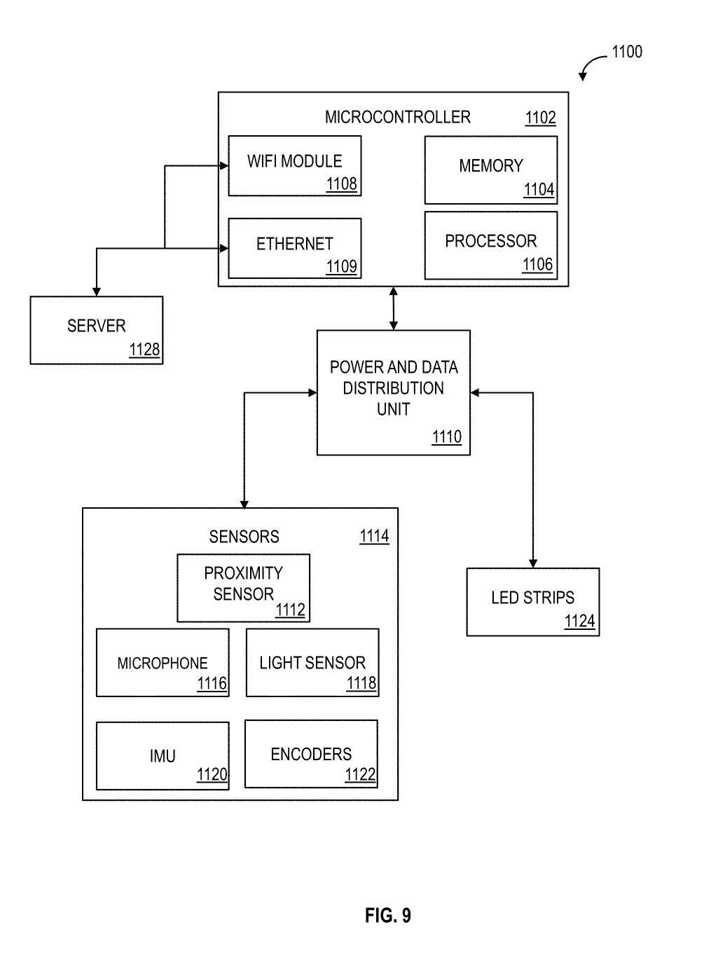

FIG. 9 shows a block diagram (1100) of a microcontroller (1102) of the pole assembly system. The microcontroller (1102) may be a non-limiting example of the onboard MCU (702) shown previously. The microcontroller (1102) may include a memory (1104) that stores instructions executable by a system processor (1106) to enable control of LED strips (1124) and additionally integrate with the sensors (1114), as discussed below. In some embodiments, the microcontroller (1102) may be able to connect to a server (1128) via a WIFI module (1108), or physical ethernet (1109) connection to enable remote control of the LED pixels and/or integration with sensors. In some embodiments, the server (1128) may be an external computer that coordinates animation effects between multiple pole displays, allowing for synchronized control of multiple pole video display systems, allowing for larger visual influence, gamification, or volumetrically mapped structures.

A power and data distribution unit (1110) routes power to the entire video display, pixel data to each LED strip (1124) and communication signals between the MCU (1102) and sensors (1114) located along the channels of the pole assembly or elsewhere.

The sensors (1114) may include a plurality of internal and external sensors. Herein, the internal sensors may refer to sensors mounted within the pole assembly system, and the external sensors may include sensors present external to the pole assembly system. In non-limiting example, the internal and the external sensors may include one or more of a proximity sensor (1112), microphone (1116), a light sensor (1118), an inertial measurement unit (1120), and an encoder (1122). The proximity sensor (1112) may be a capacitive touch sensing element that is used to locate the position of a user touching the device using a network of electrodes that are distributed radially and axially through the structure. The controller (1102) aggregates internal sensing data from the internal sensors in addition to the external sensors (also referred to as environmental sensing devices). Based on the information received from the sensors (1114), the microcontroller adjusts an output of the LED strip (1124) as discussed below.

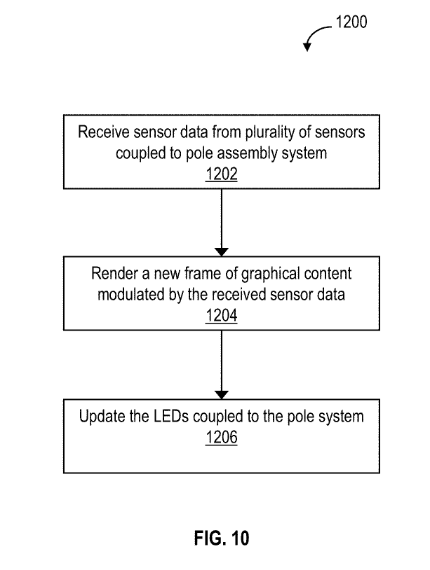

Turning now to FIG. 10, an example method (1200) for controlling the output of the LED strips based on the sensor data received from the sensors is shown. Instructions for carrying out method 1200 may be executed by a microcontroller (such as controller (1102) of FIG. 9) based on instructions stored in memory of the controller and in conjunction with signals received from sensors of the pole assembly system, such as the sensors described above with reference to FIGS. 1-9. Alternatively, the pole video display system may be used as a traditional display, capable of showing video content from external sources.

At 1202, method 1200 includes receiving sensor data from a plurality of sensors coupled to the pole assembly system. As an example, the microcontroller may receive sensor data from a proximity sensor. Based on the sensor data, the microcontroller may determine a location where a user has touched the pole system. As another example, the microcontroller may receive sensor data from a pressure sensor coupled to a dance floor indicating that a user has stepped on the dance floor. In yet another example, the microcontroller may receive sensor data from an inertial measurement unit (IMU) that a certain force has been applied to the pole assembly system. If a user strikes the pole assembly, for example, the IMU sensor detects the impact and the microcontroller may generate a particle animation, based on the magnitude of the impact as measured by the IMU. As described previously, the plurality of sensors may include both internal and external sensors coupled to the pole assembly system.

The microcontroller may generate a frame of graphical content using incoming sensor data, and outputs data to the LEDs integrated within the pole video display system. As an example, the displayed effect may include video, patterns, shapes or text formed by the array of LED pixels. In some embodiments, the microcontroller may retrieve graphic content stored in the memory or dynamically generate content and modulate the LED output accordingly. As an example, an initial display pattern may include flashing LED light in a specific sequence. However, if the ambient noise level increases above a threshold, the microcontroller may flash the LED light at a higher rate, for example. In another example, the flashing of the LED light may be synchronized with the music played in the background. If the music changes, the microcontroller may update the display pattern accordingly.

At 1206, method 1200 includes generating the signals to update the LED display with the newly rendered content.

With respect to the device, it should be further noted that the device can be a stand-alone fixture or part of a larger system. In some embodiments, multiple pole assemblies may communicate with one another by a master controller or other node in a mesh network, and the video displayed on each of the pole assemblies may be controlled to create dynamic experiences.

Ultimately, at the conclusion of these steps is a method by which a load-bearing interactive pole video display system can utilize sensors to incorporate environmental data in the video display, allowing it to act in ways such as but not limited to: ambient decoration, safety illumination, performance prop, conveyor of information, interactive system, or control device.

As used herein, the term “about” refers to plus or minus 10% of the referenced number.

Various modifications of the invention, in addition to those described herein, will be apparent to those skilled in the art from the foregoing description. Such modifications are also intended to fall within the scope of the appended claims. Each reference cited in the present application is incorporated herein by reference in its entirety.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. Reference numbers recited in the claims are exemplary and for ease of review by the patent office only, and are not limiting in any way. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting of”, and as such the written description requirement for claiming one or more embodiments of the present invention using the phrase “consisting of” is met.

The reference numbers recited in the below claims are solely for ease of examination of this patent application, and are exemplary, and are not intended in any way to limit the scope of the claims to the particular features having the corresponding reference numbers in the drawings.

What is claimed is:

1. A load-bearing interactive pole video display system (100) comprising:
a) an internal load-bearing structure (108) providing rigidity and stability to the cylindrical display;
b) a plurality of channels (304) formed in the load-boarding structure, housing a plurality of light sources (112) within;
c) a plurality of light sources comprising a cylindrical array of individually controlled LED pixels;
d) a light transmissive tube (102) enclosing the load-bearing structure, diffusing the plurality of light sources (112), and providing a uniform surface to the display system (100);
e) a plurality of sensors (1114) tracking the system's state and environment; and
f) a microcontroller (MCU) (702) attached to the display system executing a program with following functions:
(i) perform data manipulation and transmission to control and output pixel content to LED display;
(ii) communicate via wireless and/or wired connection with external devices;
(iii) display two-dimensional graphic content from a plurality of image and video sources and generate animated output based on such assets and the plurality of sensors;
(iv) integrate sensor data from sources such as capacitive touch sensors to control functionality of or modulate the displayed content; and
(v) receive and display graphic content generated or otherwise received from external sources

2. The pole video display system of claim 1, wherein the internal load-bearing structure may comprise a central tube or rod and an extruded structure with a plurality of channels for housing LED light sources, wherein the channels are effective for attaching LEDs in an unobtrusive manner that maximize blending between adjacent light sources.

3. The pole video display system of claim 1, wherein the internal load-bearing structure comprises a single piece structure that is extruded, milled or otherwise formed from a hard material.

4. The pole video display system of claim 3, wherein the hard material is steel.

5. The pole video display system of claim 2, wherein each of the central tube (108), the channel structure (110), and the light transmissive tube (102) are coaxial, wherein the plurality of channels is formed around the extruded channel structure (110), and wherein the video display is coupled to modular end fittings (104) on either end.

6. The pole video display system of claim 2, wherein the central tube (108) is comprised of steel.

7. The pole video display system of claim 2, wherein the extruded structure is comprised of aluminum.

8. The pole video display system of claim 2, wherein the light transmissive tube is comprised of polycarbonate.

9. The pole video display system of claim 1, wherein the plurality of sensors comprises internal sensors and external sensors.

10. The pole video display system of claim 9, wherein the sensors are proximity sensors (1112), touch sensors, motion sensors, temperature sensors, audio sensors, or light sensors.

11. The pole video display system of claim 1, wherein the internal load-bearing structure comprises the following:
a. each channel (305) comprises a base (402) coupled to angled sidewalls, wherein each light source is positioned on the base of the channel and projects light toward an opening;
b. a ring-shaped power and data distribution circuit board (610) coupled to an end of the light structure; and
c. a plurality of LED strips (112) directly plugged into connectors (602) positioned around the circuit board (610) to receive power.

12. The pole video display system of claim 1, wherein channels in the end fittings align with channels formed by the channel structure, allowing wiring from the display system to be routed to the MCU and power and data distribution unit located elsewhere.

13. The pole video display system of claim 9, wherein the LED display structure further comprises capacitive touch sensing units co-located with a graphical display, in communication with the MCU, the combination of which provides touch-responsive capabilities.

14. The pole video display system of claim 11, wherein the MCU (702) executes a program with following functions:
a. maintain communication and receive data from capacitive touch sensing units;
b. determine areas and positions where a user is touching the LED display system; and
c. process touch as a system input.

15. The pole video display system of claim 14, the system input is for animating or otherwise altering the graphic content, reporting to an external system, or input interface for the user.

16. The pole video display system of claim 12, wherein the pole content display is coupled to additional internal and external sensors capable of modulating the displayed content.

17. The pole video display system of claim 16, wherein the sensors are audio sensors, light sensors, inertial measurement unit (IMU) sensors, or temperature sensors.

18. The pole video display system of claim 13, wherein the executed program on the MCU includes further functions to:
a. receive and process data from one or more external and internal sensing units;
b. receive and process graphical content data from one or more external sources; and
c. receive and process playback control data from one or more external sources via an industry standard protocol.

19. The pole video display system of claim 18, wherein the industry standard protocol is DMX512, sACN, Art-Net, or OSC.
